(19) United States
(12) Patent Application Publication
(10) Pub. No.: US 2017/0033036 A1
(43) Pub. Date: Feb. 2, 2017

(54) PRINTED WIRING BOARD, SEMICONDUCTOR PACKAGE, AND METHOD FOR MANUFACTURING PRINTED WIRING BOARD

(71) Applicant: IBIDEN CO., LTD., Ogaki (JP)

(72) Inventors: Kazuki KAJIHARA, Ogaki (JP); Takema ADACHI, Ogaki (JP); Teruyuki ISHIHARA, Ogaki (JP)

(73) Assignee: IBIDEN CO., LTD., Ogaki (JP)

(21) Appl. No.: 15/223,247

(22) Filed: Jul. 29, 2016

(30) Foreign Application Priority Data
Jul. 31, 2015 (JP) 2015-151833

(51) Int. Cl. H01L 23/498; H05K 3/34; H01L 25/065; H05K 3/24

(52) U.S. Cl. CPC H01L 23/49827; H05K 3/244; H05K 3/3463; H05K 3/243; H05K 3/241; H01L 25/0657; H05K 2203/0723; H05K 2203/0574; H01L 2225/06572

(57) ABSTRACT

A printed wiring board includes a buildup wiring layer including resin insulation layers and conductive layers such that the conductive layers are laminated on the resin insulation layers, respectively, first pads formed in a center portion of a first surface of the buildup wiring layer and positioned to connect an electronic component, second pads formed on a periphery portion of the first surface of the buildup wiring layer and positioned to connect an external wiring board, a solder layer including a plating material and formed on the first pads such that the solder layer is formed on each of the first pads, conductive posts including a plating material and formed on the second pads, respectively, and a seed layer including first seed layer portions formed between the first pads and the solder layer and second seed layer portions formed between the second pads and the conductive posts.

### CROSS-REFERENCE TO RELATED APPLICATIONS

The present application is based upon and claims the benefit of priority to Japanese Patent Application No. 2015-151833, filed Jul. 31, 2015, the entire contents of which are incorporated herein by reference.

### BACKGROUND OF THE INVENTION

Field of the Invention

The present invention relates to a printed wiring board, a semiconductor package, and a method for manufacturing a printed wiring board.

Description of Background Art

U.S. Patent Application Publication No. 2010/0289134 describes an integrated-circuit packaging system having embedded interconnects. In this printed wiring board, a semiconductor device is mounted on a first-surface side recessed region, and conductive pads surrounding the device are coupled with solder balls connected to an external wiring board. The entire contents of this publication are incorporated herein by reference.

### SUMMARY OF THE INVENTION

According to one aspect of the present invention, a printed wiring board includes a buildup wiring layer including resin insulation layers and conductive layers such that the conductive layers are laminated on the resin insulation layers, respectively, first pads formed in a center portion of a first surface of the buildup wiring layer and positioned to connect an electronic component, second pads formed on a periphery portion of the first surface of the buildup wiring layer and positioned to connect an external wiring board, a solder layer including a plating material and formed on the first pads such that the solder layer is formed on each of the first pads, conductive posts including a plating material and formed on the second pads, respectively, and a seed layer including first seed layer portions formed between the first pads and the solder layer and second seed layer portions formed between the second pads and the conductive posts.

According to another aspect of the present invention, a semiconductor package includes a printed wiring board, a first semiconductor element mounted on a surface of the printed wiring board, and an external wiring board mounted on the surface of the printed wiring board. The printed wiring board includes a buildup wiring layer including resin insulation layers and conductive layers such that the conductive layers are laminated on the resin insulation layers, respectively, first pads formed in a center portion of a first surface of the buildup wiring layer and positioned to connect the first semiconductor element to the surface of the printed wiring board, second pads formed on a periphery portion of the first surface of the buildup wiring layer and positioned to connect the external wiring board to the surface of the printed wiring board, a solder layer including a plating material and formed on the first pads such that the solder layer is formed on each of the first pads, conductive posts including a plating material and formed on the second pads, respectively, and a seed layer including first seed layer portions formed between the first pads and the solder layer and second seed layer portions formed between the second pads and the conductive posts.

According to yet another aspect of the present invention, a method for manufacturing a printed wiring board includes forming a buildup wiring layer including resin insulation layers and conductive layers such that the conductive layers are laminated on the resin insulation layers, respectively, forming first pads in a center portion of a first surface of the buildup wiring layer such that the first pads are positioned to connect an electronic component, forming second pads on a periphery portion of the first surface of the buildup wiring layer such that the second pads are positioned to connect an external wiring board, forming a seed layer on the first surface of the buildup wiring layer such that the seed layer is formed on a surface including surfaces of the first pads and second pads formed on the first surface of the buildup wiring layer, forming on the seed layer a first plating-resist layer having first openings such that the first openings expose the first pads, respectively, applying electroplating using the seed layer as a power-supply layer such that a solder layer is formed on the seed layer exposed in each of the first openings, removing the first plating-resist layer from the seed layer, forming on the seed layer a second plating-resist layer having second openings such that the second openings expose the second pads, respectively, applying electroplating using the seed layer as a power-supply layer to the second pads such that conductive posts are formed on the seed layer exposed in the second openings, respectively, removing the second plating-resist layer from the seed layer, and removing the seed layer exposed by the removing of the second plating-resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a printed wiring board according to an embodiment of the present invention;

FIG. 2A is a cross-sectional view illustrating a process in a method for manufacturing the printed wiring board shown in FIG. 1;

FIG. 2B is a cross-sectional view illustrating a process in the method for manufacturing the printed wiring board shown in FIG. 1;

FIG. 2C is a cross-sectional view illustrating a process in the method for manufacturing the printed wiring board shown in FIG. 1;

FIG. 2D is a cross-sectional view illustrating a process in the method for manufacturing the printed wiring board shown in FIG. 1;

FIG. 2E is a cross-sectional view illustrating a process in the method for manufacturing the printed wiring board shown in FIG. 1;

FIG. 2F is a cross-sectional view illustrating a process in the method for manufacturing the printed wiring board shown in FIG. 1;

FIG. 2G is a cross-sectional view illustrating a process in the method for manufacturing the printed wiring board shown in FIG. 1;

FIG. 2H is a cross-sectional view illustrating a process in the method for manufacturing the printed wiring board shown in FIG. 1;

FIG. 2I is a cross-sectional view illustrating a process in the method for manufacturing the printed wiring board shown in FIG. 1;

FIG. 2J is a cross-sectional view illustrating a process in the method for manufacturing the printed wiring board shown in FIG. 1;

FIG. 2K is a cross-sectional view illustrating a process in the method for manufacturing the printed wiring board shown in FIG. 1;

FIG. 2L is a cross-sectional view illustrating a process in the method for manufacturing the printed wiring board shown in FIG. 1;

FIG. 3 is a cross-sectional view illustrating a printed wiring board according to another embodiment of the present invention;

FIG. 4 is a cross-sectional view illustrating a modified example of the embodiment shown in FIG. 1;

FIG. 5A is a cross-sectional view illustrating a process in another method for manufacturing the printed wiring board shown in FIG. 4;

FIG. 5B is a cross-sectional view illustrating a process in the other method for manufacturing the printed wiring board shown in FIG. 4;

FIG. 5C is a cross-sectional view illustrating a process in the other method for manufacturing the printed wiring board shown in FIG. 4;

FIG. 5D is a cross-sectional view illustrating a process in the other method for manufacturing the printed wiring board shown in FIG. 4;

FIG. 5E is a cross-sectional view illustrating a process in the other method for manufacturing the printed wiring board shown in FIG. 4;

FIG. 5F is a cross-sectional view illustrating a process in the other method for manufacturing the printed wiring board shown in FIG. 4;

FIG. 5G is a cross-sectional view illustrating a process in the other method for manufacturing the printed wiring board shown in FIG. 4;

FIG. 6A is a view showing a modified example of the manufacturing process of a printed wiring board shown in FIG. 5A;

FIG. 6B is a view showing a modified example of the manufacturing process of a printed wiring board shown in FIG. 5G;

FIG. 7 is a view illustrating a modified example of the embodiment shown in FIG. 3; and

FIG. 8 is a cross-sectional view illustrating a semiconductor package where a first semiconductor element and another wiring board are mounted on the printed wiring board shown in FIG. 1.

### DETAILED DESCRIPTION OF THE EMBODIMENTS

The embodiments will now be described with reference to the accompanying drawings, wherein like reference numerals designate corresponding or identical elements throughout the various drawings.

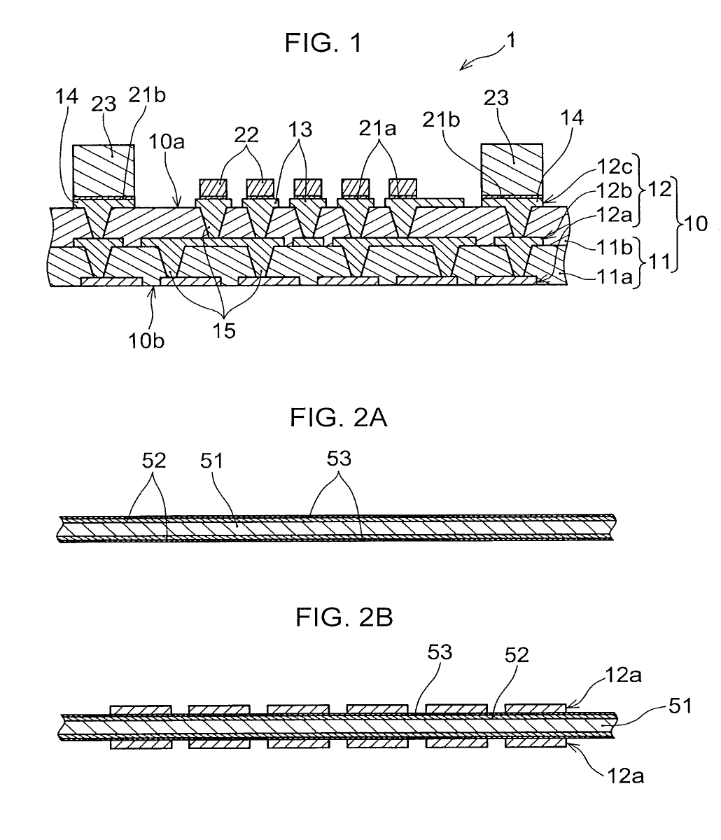

FIG. 1 is a cross-sectional view illustrating printed wiring board 1 according to an embodiment of the present invention. Printed wiring board 1 has buildup wiring layer 10, which is formed by alternately laminating resin insulation layers 11 (first resin insulation layer (11a), second resin insulation layer (11b)) and conductive layers 12 (first conductive layer (12a), second conductive layer (12b), third conductive layer (12c)), and which has first surface (10a) and second surface (10b) opposite first surface (10a). On the first-surface (10a) side of buildup wiring layer 10, first pads 13 to be connected to an electronic component such as a semiconductor element (not shown) are formed in the center portion, and second pads 14 to be connected to an external wiring board (not shown) are formed on the peripheral portion. Solder layer 22 is formed by plating on first pads 13 with first seed layer portions (21a) formed in between. Also, conductive posts 23 are formed by plating on second pads 14 with second seed layer portions (21b) formed in between. First seed layer portions (21a) and second seed layer portions (21b) are both formed to be part of the same seed layer in printed wiring board 1.

Namely, according to the present embodiment, solder layer 22 on first pads 13 to be connected to an electronic component such as a semiconductor element, and conductive posts 23 on second pads 14 to be connected to an external wiring board are each formed by plating. Here, conductive posts 23 are set taller than solder layer 22. Even when first pads 13 and second pads 14 are fine-pitched with a narrower distance and width, solder layer 22 and conductive posts 23 connected thereon are each accurately formed to have a significantly narrow width. Accordingly, accidental contact is prevented from occurring between adjacent portions of solder layer 22 or between adjacent conductive posts 23, and connection reliability is thereby enhanced. In other words, a fine-pitched wiring board is achieved. As a result, electronic devices are miniaturized.

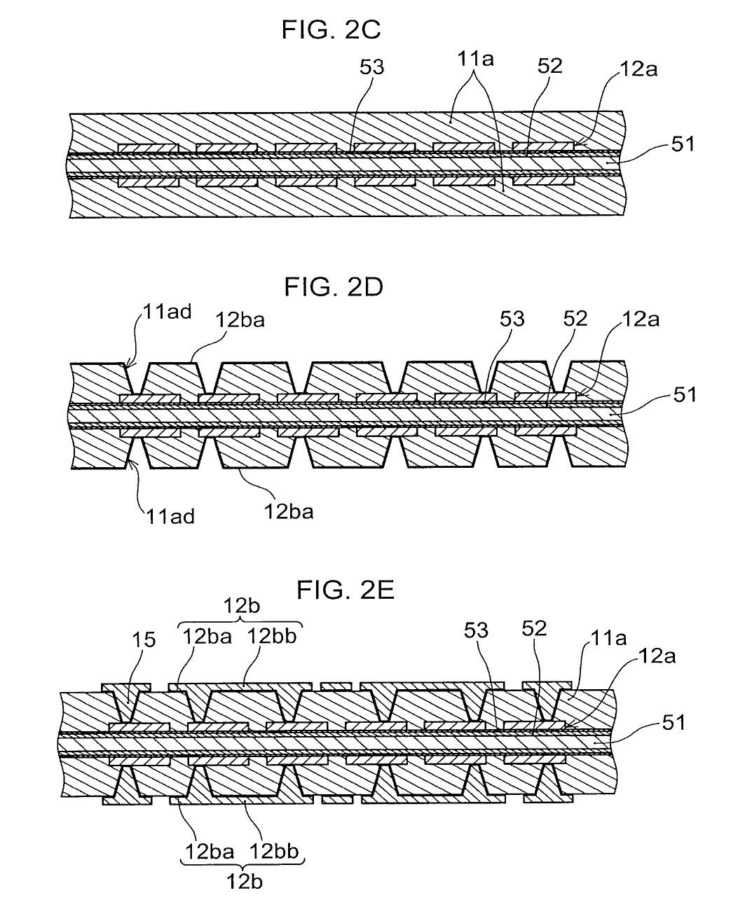

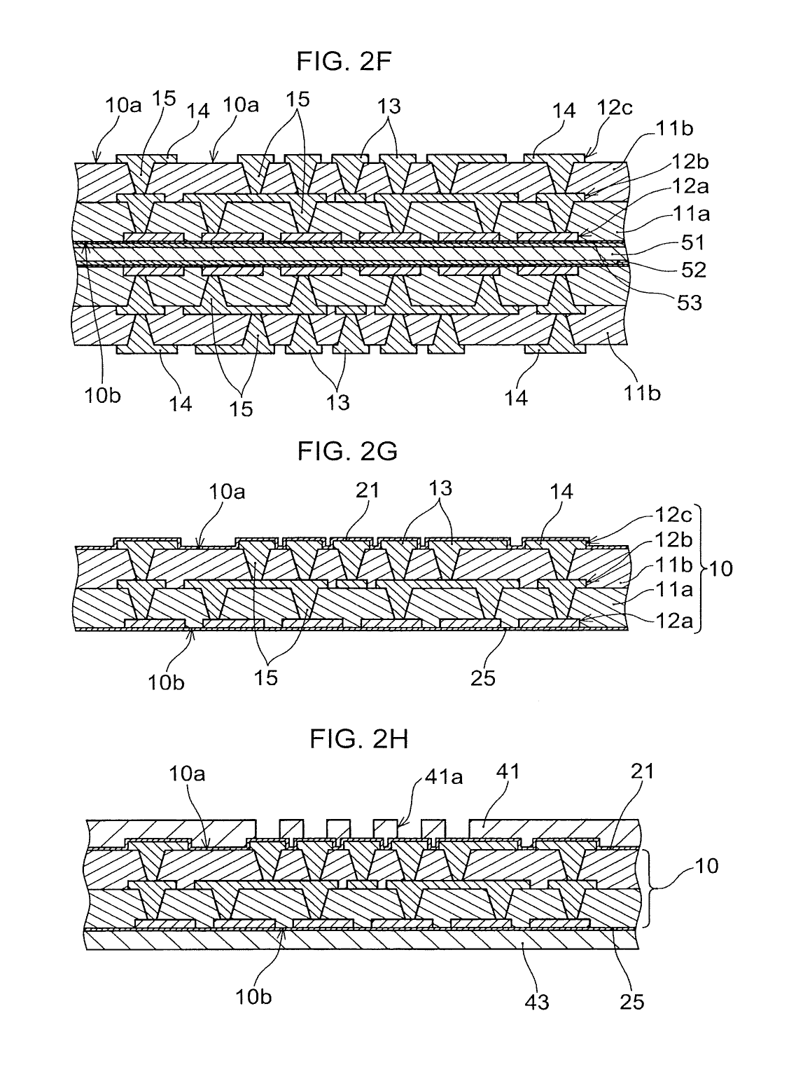

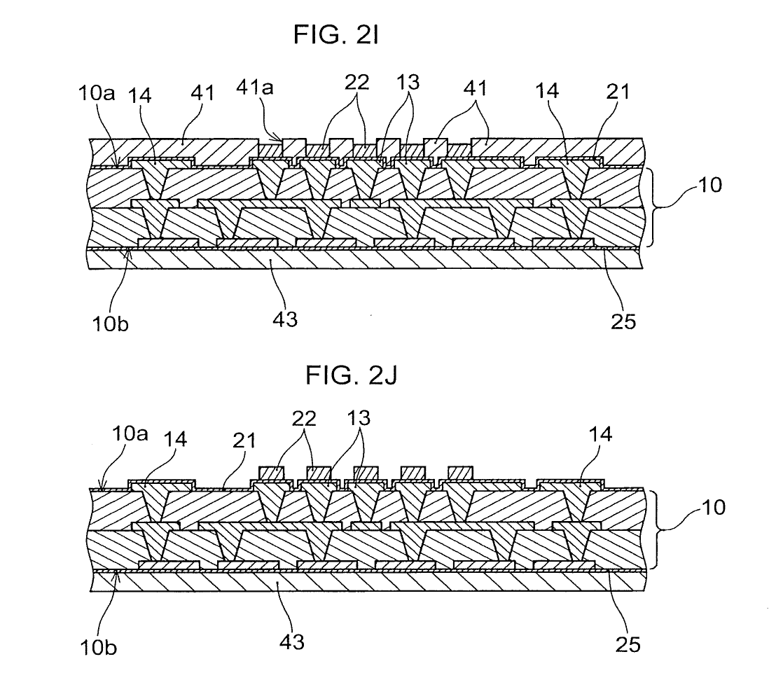

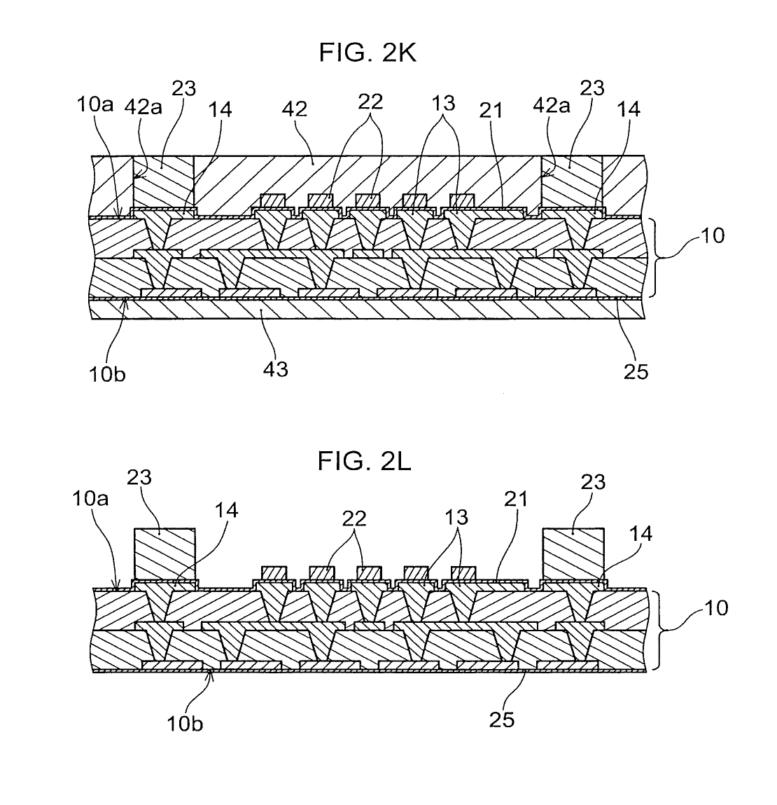

Moreover, since different materials are used for forming solder layer 22 and conductive posts 23 in the present embodiment, their electroplating procedures are applied separately. However, first and second seed layer portions (21a, 21b) for supplying power 25 during electroplating are formed at the same time, that is, first and second seed layer portions (21a, 21b) are both formed to be part of the same seed film. Thus, forming two seed layers 21 is accomplished by a single electroplating process (see FIG. 2G), resulting in no increase in the number of manufacturing procedures. Actual manufacturing procedures are described later.

Buildup wiring layer 10 is formed with two resin insulation layers 11 (first and second resin insulation layers (11a, 11b)) and a total of three conductive layers 12 (first, second and third conductive layers (12a, 12b, 12c)) formed respectively on both surfaces of resin layers. Namely, FIG. 1 shows an example of triple-layer buildup wiring layer 10. However, the numbers of resin insulation layers 11 and conductive layers 12 are not limited to those in the example, and may be selected appropriately according to the circuit structure. Buildup wiring layer 10 may have a double-layer structure formed with single resin insulation layer 11 and conductive layers positioned on both of its surfaces.

Alternatively, buildup wiring layer 10 may be formed to have a four-layer structure or greater.

It is an option to form resin insulation layer 11 using prepreg that contains a core material such as glass fibers (not shown), for example. When a later-described electronic component such as a semiconductor element is mounted, resin insulation layer 11 with a core material is more likely to suppress warping or the like caused by the difference in thermal expansion coefficients between the electronic component and resin insulation layer 11. Examples of resin insulation layer 11 are epoxy resin and the like. Epoxy resin may contain inorganic filler such as silica (SiO₂) filler. The thickness of resin insulation layer 11 is set to be in a range of 10 μm to 100 μm. When another wiring board is mounted on the first-surface (10a) side of buildup wiring layer 10, a later-described package-on-package (POP) is formed. Printed wiring board 1 may be used as the lower wiring board of a POP.

First conductive layer (12a) is embedded in the surface of first resin insulation layer (11a), and only one of its surfaces is exposed from first resin insulation layer (11a).

As described, first conductive layer (12a) embedded in first resin insulation layer (11a) contributes to making a thinner printed wiring board 1. Moreover, adhesion is enhanced between first conductive layer (12a) and first resin insulation layer (11a). As described later, since wiring is formed without employing etching, finer wiring is achieved. As a result, demand, especially for a high-density and fine-pitched wiring board, is satisfied.

Each of conductive layers 12 (first to third conductive layers (12a, 12b, 12c)) is formed by electroplating, for example, as described later. By employing a so-called additive method, fine patterns are precisely formed. A material used in electroplating for conductive layers is copper, for example. However, it is also an option to use other metals such as nickel. Each of first to third conductive layers (12a, 12b, 12c) is formed to have a thickness in a range of 3 μm to 20 μm, for example. Via conductors 15 are formed to connect between first conductive layer (12a) and second conductive layer (12b) and between second conductive layer (12b) and third conductive layer (12c). Via conductors 15 are formed in each of first and second resin insulation layers (11a, 11b). As described later, via conductors 15 are formed in conductive connection holes by using a laser irradiated on either surface of resin insulation layer 11, for example. The diameter of a conductive connection hole is greater on the side irradiated by laser light than that on the side opposite the laser-irradiated side (on the bottom side of a hole). In the example shown in FIG. 1, laser light is irradiated from the upper side of the drawing. Thus, the upper diameter (width) of a conductive connection hole is greater than the lower diameter (width). Accordingly, via conductors 15 embedded in the conductive connection holes have a greater upper width (diameter) than the lower width (diameter). Namely, via conductors 15 taper, becoming thinner toward one end. In the example shown in FIG. 1, first pads 13 and second pads 14 are each formed on the greater-diameter side of via conductor 15.

The number of first pads 13 is not limited to that shown in FIG. 1. For example, the number of first pads 13 is determined to correspond to the number of electrodes of an electronic component to be connected to first pads 13, while a layout of first pads 13 is determined to correspond to the positions of electrodes of the electronic component. Examples of the electronic component are semiconductor elements, passive elements (such as capacitors and resistors), interposers with rewiring layers, semiconductor elements with rewiring layers, WLPs (wafer level packages) and the like.

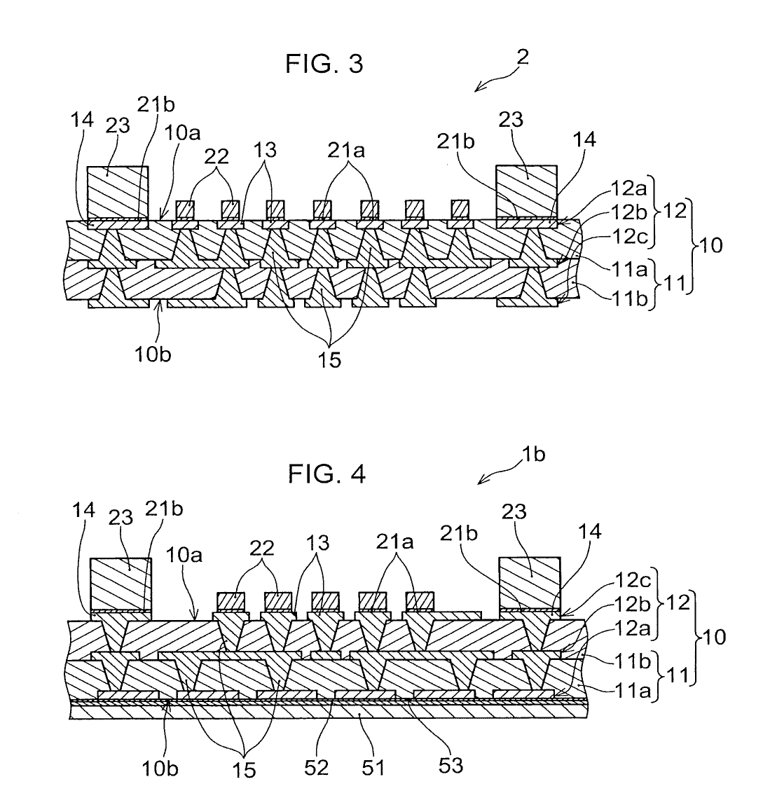

When first pads 13 and second pads 14 are each formed on via conductor 15, first and second pads (13, 14) are set to be greater than at least the end surface of via conductor 15 on the side where first and second pads (13, 14) are formed. As shown in FIG. 1, when first and second pads (13, 14) are formed on the greater-diameter side of via conductor 15, the widths of first and second pads (13, 14) are set greater. Accordingly, the distance between pads is narrowed, making it difficult to increase the number of pads. Meanwhile, the tapering direction of via conductors 15 may be set to be opposite. An example of such a structure is described later with reference to FIG. 3.

Next, a method for manufacturing a printed wiring board shown in FIG. 1 is described with reference to FIG. 2A-2L.

As shown in FIG. 2A, base plate 51 and metal film (metal foil) 53 with attached carrier copper foil 52, for example, are prepared. Metal film 53 and carrier copper foil 52 of the metal film with attached carrier copper foil are bonded using a thermoplastic adhesive (not shown), for example. Carrier copper foil 52 of the metal film with attached carrier copper foil is thermo-pressed onto base plate 51 made of prepreg. When carrier copper foil 52 and metal film 53 are bonded by a thermoplastic adhesive, it is easier to separate carrier copper foil 52 and metal film 53 by raising the temperature and detaching them from each other in a later process. It is an option for carrier copper foil 52 and metal film 53 to be bonded only on the margins around their peripheries. As long as it has appropriate rigidity, base plate 51 is not limited to any specific material. For example, base plate 51 may be made of copper or be an insulative plate made of ceramics. Metal film 53 may be a metal foil, for example, preferably a copper foil with a thickness in a range of 1 μm to 6 μm. However, the material of metal film 53 is not limited to the above. As long as a material is capable of forming first conductive layer (12a) (see FIGS. 1 and 2B) on its surface, it is suitable for forming metal film 53. For example, it may be a film or foil made of other metals such as nickel.

FIG. 2A-2F show a method for manufacturing an embodiment where first conductive layer (12a) or the like is formed on both sides of base plate 51. Two first conductive layers (12a) or the like are formed simultaneously. However, it is an option to form first conductive layer (12a) or the like only on one side of base plate 51. In the description below, a method for manufacturing an embodiment is described by referring to one side of base plate 51, while descriptions and reference numerals in the drawings are omitted on the other side when applicable. The drawing of base plate 51 is selected for the sake of description and is not intended to show the actual thickness.

On metal film 53, a resist pattern (not shown) is formed to have openings in positions for forming conductive patterns of first conductive layer (12a). Electroplating is applied to form plated conductors in the resist pattern openings by using metal film 53 as the seed layer. When the resist pattern is removed, first conductive layer (12a) with predetermined conductive patterns is formed as shown in FIG. 2B. Without etching the conductive layer, conductive patterns are formed only through electroplating so that first conductive layer (12a) is formed with fine-pitch conductor (wiring) patterns. First conductive layer (12a) is preferred to be formed with a thickness in an approximate range of 5 μm to 25 μm. Copper is preferred as the material for first conductive layer (12a). First conductive layer (12a) is formed by a simplified process at a lower price. The material for first conductive layer (12a) is not limited to copper. For example, nickel, composite layers of gold-nickel or gold-nickel-copper and the like may also be used.

Then, as shown in FIG. 2C, first resin insulation layer (11a) is formed on metal film 53 and on first conductive layer (12a). A film-type insulative material, for example, 25 is laminated on first conductive layer (12a) and thermo-pressed. For example, first resin insulation layer (11a) may be formed using epoxy resin that does not contain reinforcing material. However, first resin insulation layer (11a) may also be formed using a material formed by impregnating epoxy resin or other resin composition into reinforcing material such as glass fibers. Resin compositions of epoxy resin or the like may contain inorganic fillers such as silica in a range of 30 mass % to 80 mass %. First resin insulation layer (11a) is formed to have a thickness in a range of 10 μm to 100 μm, for example.

Next, as shown in FIG. 2D, conductive connection holes (11ad) are formed to penetrate through first resin insulation layer (11a). Conductive connection holes (11ad) are preferred to be formed by irradiating a CO₂ laser at positions for forming conductive connection holes (11ad) in first resin insulation layer (11a). When laser light is irradiated from the surface of first resin insulation layer (11a) opposite first conductive layer (12a), conductive connection holes (11ad) are formed tapering toward first conductive layer (12a).

As shown in FIG. 2D, metal layer (12ba) is formed by, for example, chemical plating (electroless plating) on the inner side of conductive connection holes (11a) and on the surface of first resin insulation layer (11a). Metal layer (12ba) may also be formed by sputtering, vacuum deposition or the like. Copper is preferred to be used for forming metal layer (12ba), but that is not the only option. For example, it may be a Ti/Cr sputtered layer. Metal layer (12ba) is formed to have a thickness in an approximate range of 0.05 μm to 1.0 μm.

Then, as shown in FIG. 2E, electroplated film (12bb) is formed by electroplating using metal layer (12ba) as the seed layer, for example. On first resin insulation layer (11a), second conductive layer (12b) is formed with metal layer (12ba) and electroplated film (12bb). In conductive connection holes (11ad), via conductors 15 are formed with metal layer (12ba) and electroplated film (12bb). Conductive patterns (wiring patterns) of second conductive layer (12b) are formed when a plating resist (not shown) is formed having openings at predetermined positions and when electroplated film (12bb) is formed in the openings. The openings of the plating-resist layer are formed on positions for forming conductive patterns of second conductive layer (12b) and on conductive connection holes (11ad). After electroplated film (12bb) is formed, the plating-resist layer (not shown) is removed. Metal layer (12ba) exposed after the removal of the plating-resist layer is etched away. As a result, second conductive layer (12b) is formed as shown in FIG. 2E. Hereinafter, metal layer (12ba) and electroplated film (12bb) will not be distinguished from each other and will be collectively referred to as second conductive layer (12b). Materials for metal layer (12ba) and electroplated film (12bb) are not particularly limited, but copper is preferred. Second conductive layer (12b) is preferred to have a thickness in a range of 5 μm to 30 μm.

Next, by repeating the same procedures shown in FIG. 2C-2E, second resin insulation layer (11b) and third conductive layer (12c) are formed on second conductive layer (12b) and first resin insulation layer (11a) as shown in FIG. 2F. Third conductive layer (12c) and second conductive layer (12b) are connected when via conductors 15 are formed by employing the same procedures shown in FIG. 2D-2E. The example shown in FIG. 1 shows buildup wiring layer 10, which has a triple-layer structure formed by laminating resin insulation layers and conductive layers having predetermined wiring patterns. To make a buildup wiring layer 10 that has more layers, a desired number of layers are formed by repeating the procedures shown in FIG. 2C-2E. Alternatively, it is an option for buildup wiring layer 10 to have only one set of conductive layer and resin insulation layer, or to have a double-layer structure formed with one resin insulation layer and conductive layers formed on both of its surfaces.

In the example shown in FIG. 1, buildup wiring layer 10 has a triple-layer structure. In third conductive layer (12c) positioned on the first-surface (10a) side of buildup wiring layer 10, first pads 13 to be connected to an electronic component are formed in the center, and second pads 14 to be connected to an external wiring board are formed on the periphery. First and second pads (13, 14) are formed the same as the aforementioned conductive patterns of second conductive layer (12b). Namely, openings are formed in a plating-resist layer corresponding to the patterns of first and second pads (13, 14), and then electroplating is applied to form first and second pads (13, 14).

Next, base plate 51 and carrier copper foil 52 are removed. Two laminates are obtained by removing base plate 51 and carrier copper foil 52. As described above, carrier copper foil 52 and metal film 53 are bonded by a thermoplastic resin or the like. Therefore, when the temperature is raised and pressure is exerted, base plate 51 and carrier copper foil 52 are easily separated from metal film 53, exposing the surface of metal film 53 to which carrier copper foil 52 was bonded. When carrier copper foil 52 and metal film 53 are bonded only on their peripheries, they are easily separated by cutting the inner side of the bonded portions. After the above process, metal film 53 exposed by the removal of carrier copper foil 52 is etched away. Note that FIG. 2G-2L referred to in the following descriptions show only the printed wiring board having base plate 51 and carrier copper foil 52.

As shown in FIG. 2G, seed layer 21 is formed on the entire surface of buildup wiring layer 10 including first surface (10a) and the surfaces of first and second pads (13, 14) of third conductive layer (12c). Seed layer 21 is formed to have a thickness in an approximate range of 0.05 μm to 1 μm. Seed layer 21 is formed by electroless copper plating or the like the same as in the aforementioned metal layer (12ba) in buildup wiring layer 10. Instead of electroless plating, seed layer 21 may also be formed by sputtering, vacuum deposition, CVD or the like. Seed layer 21 will be a power-supply layer when later-described solder layer 22 and conductive posts 23 are formed by electroplating. On second surface (10b) of buildup wiring layer 10, metal layer 25 is formed to have approximately the same thickness. However, third plating-resist layer 43 may be formed prior to forming seed layer 21. In such a case, metal layer 25 is formed on third plating-resist layer 43. Metal layer 25 on third plating-resist layer 43 is removed together with third plating-resist layer 43.

Next, as shown in FIG. 2H, first plating-resist layer 41 is formed on the entire surface of seed layer 21 positioned on the first-surface (10a) side of buildup wiring layer 10. First openings (41a) are formed in first plating-resist layer 41, corresponding to portions to form solder layer 22 (see FIG. 1). First openings (41a) are formed by exposure and development. Therefore, first openings (41a) are formed to be substantially vertical, and solder layer 22 to be embedded in first openings (41a) are thereby formed to have substantially the same width in a height direction. In addition, PET film 43, for example, is formed on the entire second-surface (10b) side surface (on metal layer 25) of buildup wiring layer 10.

Then, electroplating is applied by supplying power to seed layer 21 so that solder layer 22 are formed on seed layer 21 exposed in first openings (41a) as shown in FIG. 2I. Tin (Sn) solder plating, for example, is employed.

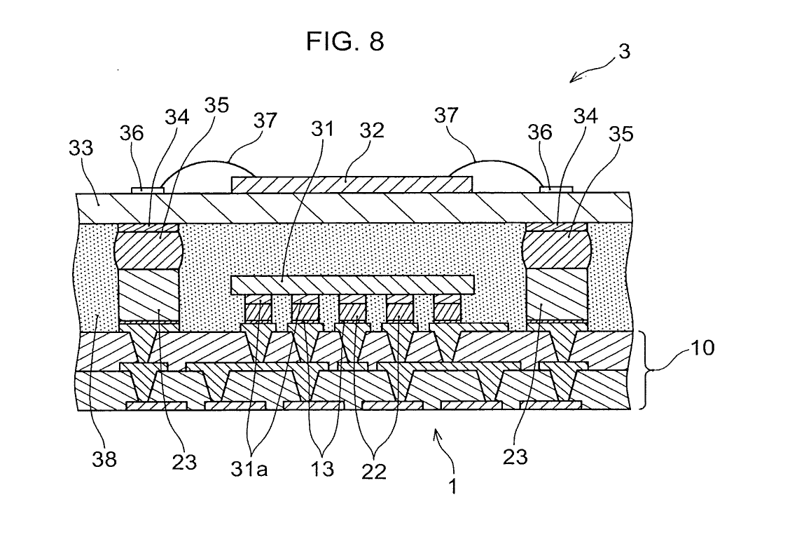

Next, as shown in FIG. 2J, first plating-resist layer 41 is removed. Then, as shown in FIG. 2K, second plating-resist layer 42 is formed on the entire first-surface (10a) side surface of buildup wiring layer 10, covering seed layer 21 and solder layer 22. Second openings (42a) are formed in second plating-resist layer 42, exposing portions of second pads 14. Second plating-resist layer 42 is formed to have a thickness substantially the same as or slightly greater than the height of conductive posts 23. Namely, second plating-resist layer 42 is formed to have a height that can encapsulate first semiconductor element 31 (see FIG. 8) to be mounted on solder layer 22. The same as the aforementioned first openings (41a), second openings (42a) are also formed by exposure and development to have substantially vertical wall surfaces. Therefore, conductive posts 23 to be embedded in the openings are formed to have substantially the same width in a height direction. Electroplating is applied by supplying power to seed layer 21, and a metal layer is formed on seed layer 21 exposed in second openings (42a) of second plating-resist layer 42. Namely, conductive posts 23 are formed by electroplating using the same seed layer 21 that was used for forming the aforementioned solder layer 22. The present embodiment is characterized by using the same seed layer 21 for separate procedures. The material of conductive posts 23 is not particularly limited, but copper is preferred due to its lower price and lower resistance. As for a plating liquid for forming copper conductive posts 23, a copper sulfate plating liquid or the like may be used, for example. The height (plating thickness) of conductive posts 23 is controlled by the duration of the plating process. Accordingly, a desired height is achieved. Depending on the desired height of conductive posts 23, electroplating may be applied a few times.

Next, as shown in FIG. 2L, second plating-resist layer 42 and PET film 43 are entirely removed. As a result, in buildup wiring layer 10, solder layer 22 and conductive posts 23 are respectively formed on first pads 13 and second pads 14 with seed layer 21 positioned in between.

Next, etching is applied to remove unwanted exposed portions of seed layer 21 where neither solder layer 22 nor conductive post 23 is formed, while metal layer 25 on the second-surface (10b) side of buildup wiring layer 10 is removed. Accordingly, seed layer 21 is divided into first seed layer portions (21a) which remain beneath solder layer 22 and second seed layer portions (21b) which remain beneath conductive posts 23. As a result, printed wiring board 1 shown in FIG. 1 is obtained.

Although not shown in the drawings, it is an option to form surface protection film such as metal film of Ni/Au or OSP on a surface of third conductive layer (12c) and exposed surfaces of conductive posts 23.

FIG. 3 shows a cross-sectional view, the same as in FIG. 1, according to another embodiment of the present invention. In the present embodiment, first and second pads (13, 14) are formed on the smaller-diameter side of tapered via conductors 15. Namely, via conductors 15 are formed to have a diameter increasing from first surface (10a) toward second surface (10b) of buildup wiring layer 10. Accordingly, first and second pads (13, 14) are also formed to have smaller widths. As a result, the width between pads is sufficiently secured, thereby preventing problems such as short circuiting between adjacent pads. In addition, the number of pads can be increased, enabling connection with an even finer-pitched electronic component and external wiring board.

In printed wiring board 2 shown in FIG. 3, solder layer 22 and conductive posts 23 are formed in a structure made by inverting buildup wiring layer 10 shown in FIG. 1. However, the structure of the example shown in FIG. 3 is not formed simply by turning buildup wiring layer 10 shown in FIG. 1 upside down. The structure of buildup wiring layer 10 is modified; that is, the number of first pads 13 is increased, making it easier to precisely mount a fine-pitched semiconductor element.

To manufacture printed wiring board 2, first and second pads (13, 14) are formed on the base-plate 51 side in the aforementioned manufacturing process. After buildup wiring layer 10 is formed, first and second pads (13, 14) are exposed by the removal of base plate 51 and metal film 53. Next, after seed layer 21 is formed on the exposed surface, solder layer 22 and conductive posts 23 are formed by the same procedures described earlier. Accordingly, printed wiring board 2 shown in FIG. 3 is obtained. When solder layer 22 and conductive posts 23 are formed, it is an option to laminate second base plate 55 on the third conductive-layer (12c) side of buildup wiring layer 10 and then to proceed to the same manufacturing processes as above. By so doing, printed wiring board (2b) is obtained as shown in later-described FIG. 7. If second base plate 55 is not laminated, PET film may be formed on the third conductive-layer (12c) side when solder layer 22 and conductive posts 23 are formed.

FIG. 4 is a modified example of printed wiring board 1 shown in FIG. 1, illustrating yet another embodiment of the present invention. In printed wiring board (1b), base plate 51 is laminated on the second-surface (10b) side of printed wiring board 1 shown in FIG. 1. Namely, unlike the base plate 51 removed in a process shown in FIG. 2G, solder layer 22 and conductive posts 23 are formed without removing base plate 51 in the present example. Printed wiring board (1b) is prevented from warping or bending. The structure shown in FIG. 4 is capable of mounting an electronic component to be directly connected to first pads 13, while mounting an external wiring board on conductive posts 23 connected to second pads 14. Since buildup wiring layer 10 is stabilized by base plate 51, manufacturing procedures are significantly easier to employ. Then, base plate 51 is removed. Electronic components and external wiring boards 33 are most likely to be mounted at high yield.

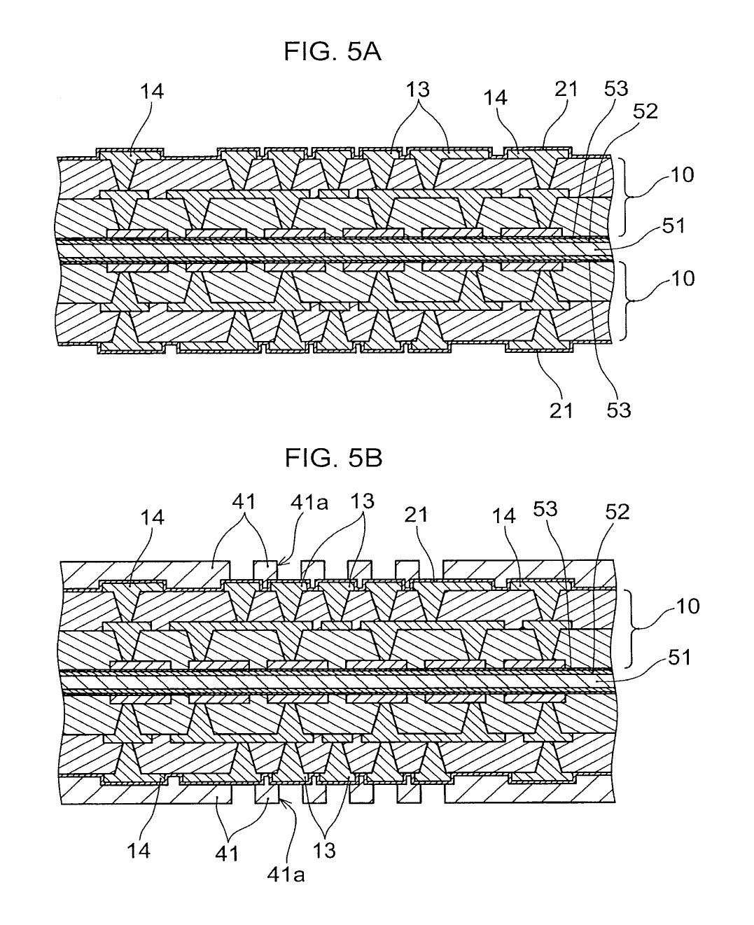

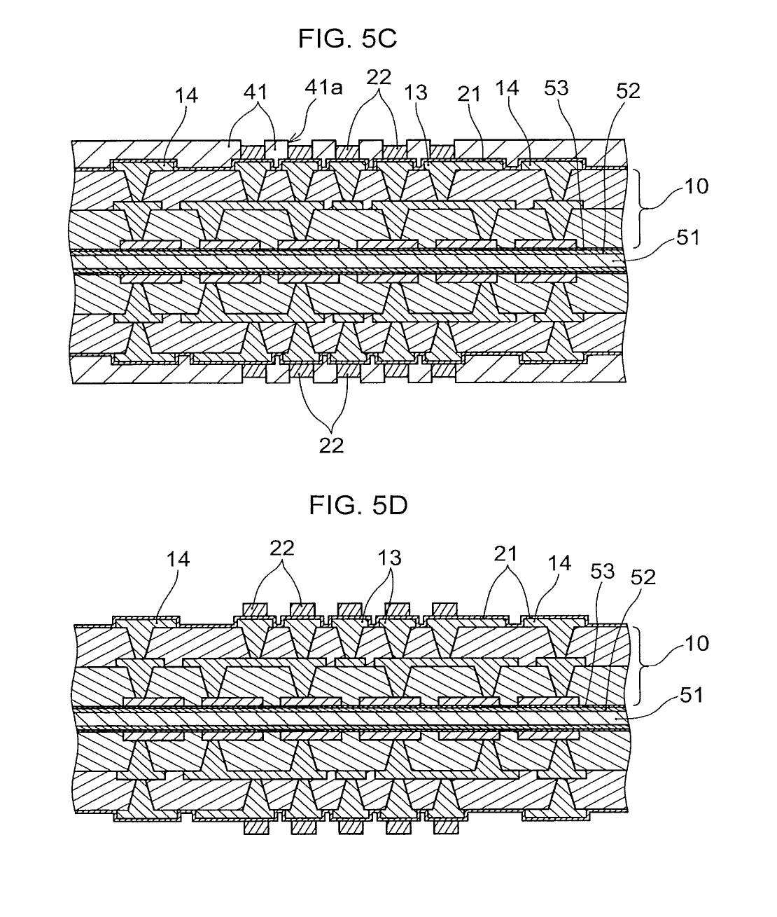

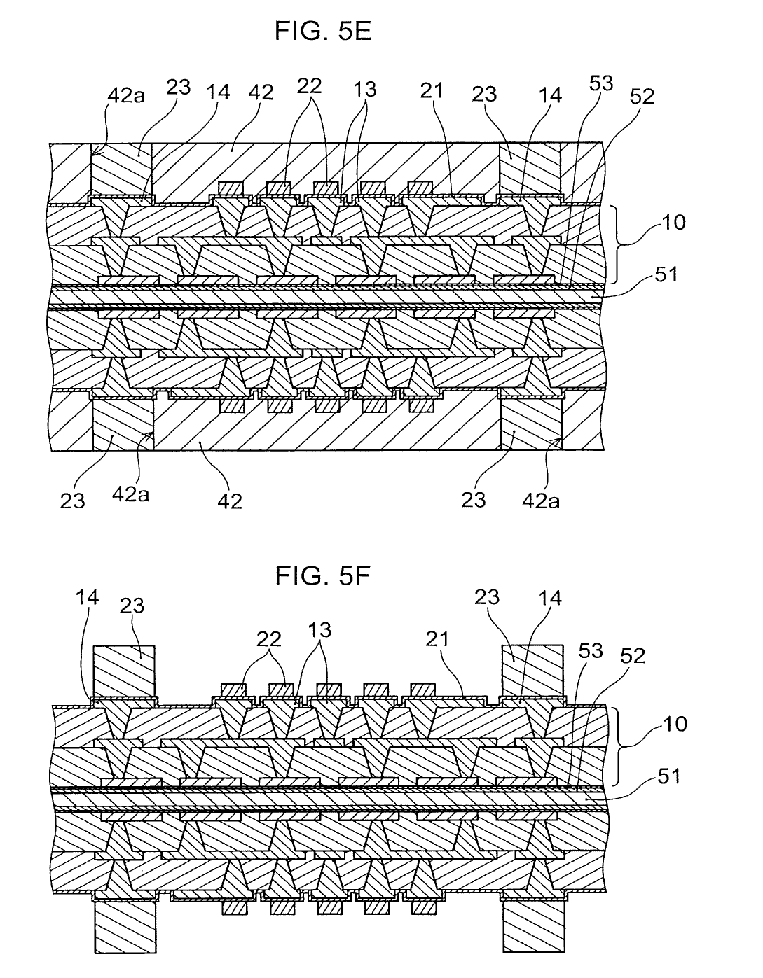

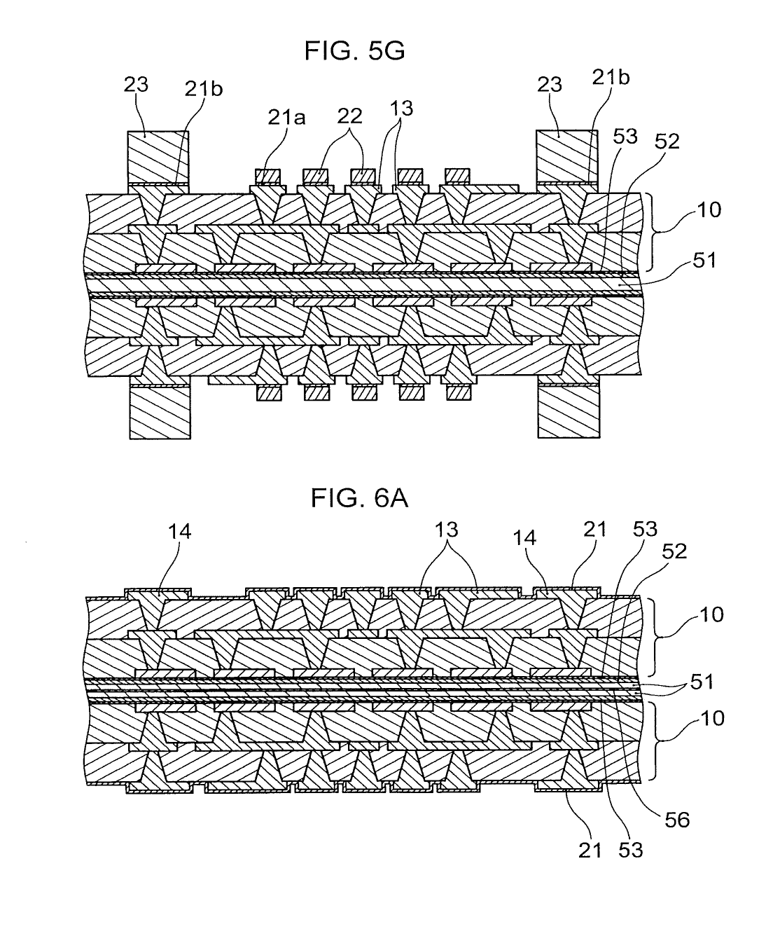

Printed wiring board (1b) is manufactured by employing the same method following the aforementioned processes shown in FIG. 2A-2L. Processes following the process in FIG. 2F are shown in FIG. 5A-5G.

FIG. 5A is a view corresponding to a process in FIG. 2G following the process in FIG. 2F. Namely, seed layer 21 is formed by electroless plating, for example, without removing base plate 51 after the process in FIG. 2F. Thus, buildup wiring layers 10 remain bonded on both sides of base plate 51 as shown in FIG. 5A. Seed layer 21 is formed on the exposed surface of buildup wiring layer 10.

As shown in FIG. 5B, first plating-resist layer 41 is formed on the entire surface of seed layer 21, and then first openings (41a) are formed on first pads 13. A detailed description is omitted here since the process is the same as in the aforementioned process shown in FIG. 2H. In the present embodiment, since buildup wiring layers 10 are formed on both sides of base plate 51, PET film or the like is not necessary to form since the second-surface (10b) of buildup wiring layer 10 is not exposed.

As shown in FIG. 5C, Sn plating is applied. Plating film is formed on portions of seed layer 21 exposed in first openings (41a), in which solder layer 22 is formed. As shown in FIG. 5D, first plating-resist layer 41 is removed. Since first plating-resist layer 41 is formed on both sides, first plating-resist layer 41 is removed simultaneously from both sides.

As shown in FIG. 5E, second plating-resist layer 42 is formed on the entire surface of seed layer 21 and solder layer 22. Then, second openings (42a) are formed to correspond to portions of second pads 14 for forming conductive posts 23. Electroplating is applied by supplying power to seed layer 21. Accordingly, conductive posts 23 are formed on seed layer 21 exposed in second openings (42a).

As shown in FIG. 5F, second plating-resist layer 42 is completely removed.

As shown in FIG. 5G, etching is applied to remove unwanted exposed portions of seed layer 21 where neither solder layer 22 nor conductive post 23 is formed. The procedure is also the same as the aforementioned etching procedure of seed layer 21. The etching procedure divides seed layer 21 into first seed layer portions (21a) and second seed layer portions (21b), the same as above. However, since base plate 51 is still bonded thereon, metal film 53 remains as is. If one side of base plate 51 is separated from base plate 51 in the structure shown in FIG. 5G, the one side will be printed wiring board 1 shown in FIG. 1, and the other side with remaining base plate 51 will be printed wiring board (1b) shown in FIG. 4.

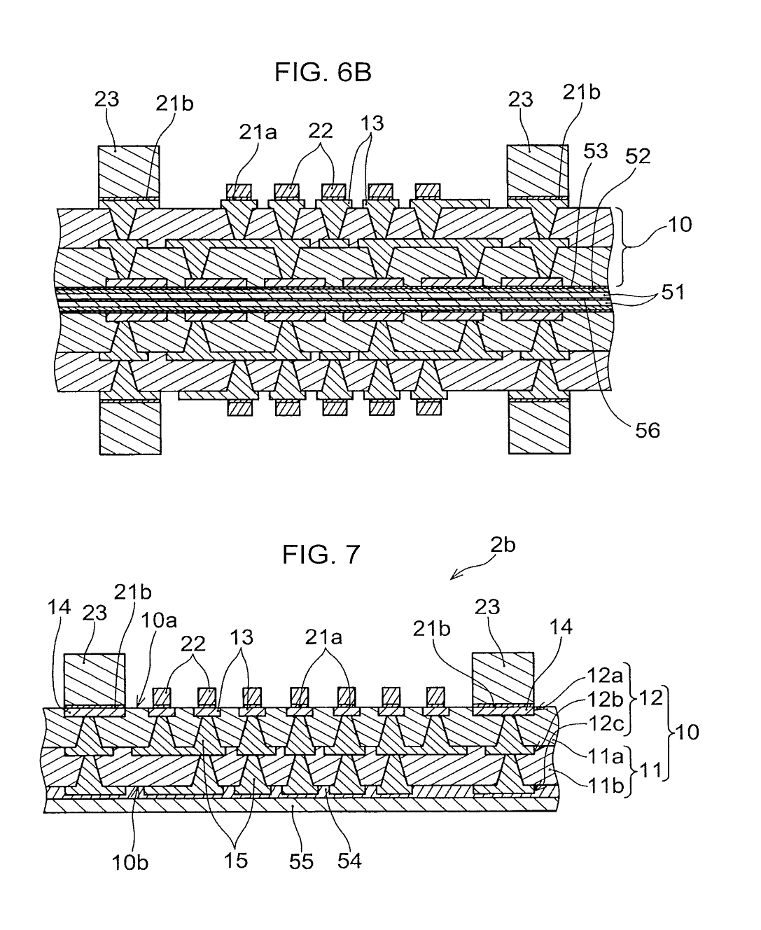

However, as shown in FIG. 6A and 6B, base plate 51 may be formed by laminating two sheets of prepreg bonded with easily removable adhesive 56. Removing adhesive 56 results in two printed wiring boards (1b) each having base plate 51. FIG. 6A corresponds to FIG. 5A, and FIG. 6B corresponds to FIG. 5G. Although drawings of the present embodiment are omitted except for FIG. 6A and 6B, base plate 51 shown in FIG. 6A is used from the starting process (FIG. 2A). In FIG. 6A and 6B, the structures except for adhesive 56 are respectively the same as those in FIG. 5A and 5G. Accordingly, their descriptions are omitted here.

In the example shown in FIG. 7, printed wiring board 2 shown in FIG. 3 is fixed to second base plate 55 by easily removable adhesive 54. Tapered via conductors 15 in buildup wiring layer 10 are formed to have a diameter that increases toward second base plate 55.

FIG. 8 shows an example of semiconductor package 3 where first semiconductor element 31 and another wiring board 33 are mounted on printed wiring board 1 shown in FIG. 1, and second semiconductor element 32 is further mounted on wiring board 33. Namely, electrodes (31a) of first semiconductor element 31 are mounted by solder reflow or the like onto solder layer 22 of printed wiring board 1 shown in FIG. 1. Bumps 35 formed on pads 34 of separately formed wiring board 33 are connected to conductive posts 23 of printed wiring board 1. Then, underfill 38 is formed by using a resin such as epoxy resin to encapsulate and protect first semiconductor element 31 in the above stage. In the example shown in FIG. 8, second semiconductor element 32 is further mounted on wiring board 33 and connected to pads 36 by bonding wires 37. However, mounting second semiconductor element 32 is optional.

The structure and materials of external wiring board 33 are not particularly limited. For example, wiring board 33 may be a printed wiring board formed with resin insulation layers and conductive layers made of copper foil or the like. It is also another option to structure wiring board 33 by forming circuits in an insulative plate made of inorganic material such as alumina.

Any conductive material, for example, solder, gold, copper or the like, may be used for bumps 35. Bumps 35 are formed on electrode pads 34 formed on one surface of wiring board 33.

First semiconductor element 31 is connected to solder layer 22 of printed wiring board 1. First semiconductor element 31 is connected to first pads 13 through electrodes (31a) and solder layer 22. Examples of first semiconductor element 31 are a microcomputer, memory, ASIC and the like.

First semiconductor element 31 is enveloped by encapsulating resin. Encapsulating resin protects first semiconductor element 31 from external stress and humidity, and also alleviates stress on bonded portions caused by changes in the surrounding temperature. Accordingly, connection reliability of first semiconductor element 31 is thought to be enhanced. In the example shown in FIG. 8, underfill 38 made of epoxy resin is filled in the entire gap between wiring board 33 and printed wiring board 1.

In the example shown in FIG. 8, second semiconductor element 32 is mounted on wiring board 33. Electrodes (not shown) of second semiconductor element 32 are connected to bonding pads 36 on wiring board 33 through wires 37. Semiconductor element 32 may also be mounted by flip-chip bonding, the same as first semiconductor element 31.

According to a semiconductor package of the present embodiment, since solder layer 22 and conductive posts 23 are precisely formed on first and second pads (13, 14) in printed wiring board 1, high connection reliability is achieved when fine-pitched wiring board 33 and semiconductor elements (31, 32) are mounted.

In the aforementioned embodiment, printed wiring board 1 shown in FIG. 1 is used in the semiconductor package. However, the aforementioned printed wiring boards (1b, 2, 2b) and the like may also be applied for the semiconductor package in the embodiment.

In a structure for connecting solder balls to conductive pads, it is thought that the solder balls do not have a consistent shape. If the outlines of solder balls are inconsistent, it is thought that the distance between adjacent solder balls is widened so as to prevent them from touching each other. Such a structure is not preferable for fine-pitched conductive pads. The connection reliability of the conductive pads and the solder balls is likely to be lowered.

A printed wiring board according to an aspect of the present invention is structured with a buildup wiring layer formed by alternately laminating a resin insulation layer and a conductive layer and having a first surface and its opposing second surface; first pads formed in the center of the first surface of the buildup wiring layer to be connected to an electronic component; second pads formed on the periphery of the first surface of the buildup wiring layer to be connected to an external wiring board; a solder layer formed by plating on the first pads with first seed layer portions positioned in between; and conductive posts formed by plating on the second pads with second seed layer portions positioned in between. The first and second seed layer portions are both formed to be part of the same seed layer.

A semiconductor package according to another aspect of the present invention is structured with a printed wiring board having a first semiconductor element mounted on one of its surfaces and an external wiring board mounted on its other surface. The printed wiring board is structured with a buildup wiring layer formed by alternately laminating a resin insulation layer and a conductive layer and having a first surface and its opposing second surface; first pads formed in the center of the first surface of the buildup wiring layer to be connected to an electronic component; second pads formed on the periphery of the first surface of the buildup wiring layer to be connected to an external wiring board; a solder layer formed by plating on the first pads with first seed layer portions positioned in between; and conductive posts formed by plating on the second pads with second seed layer portions positioned in between. The first and second seed layer portions are both formed to be part of the same seed layer. The first semiconductor element is mounted on the printed wiring board through the solder layer, and the external wiring board is mounted on the printed wiring board through the conductive posts.

A method for manufacturing a printed wiring board according to yet another aspect of the present invention includes following processes: by alternately laminating a resin insulation layer and a conductive layer, forming a buildup wiring layer which has a first surface and its opposing second surface; in the center of the first surface of the buildup wiring layer, forming first pads to be connected to an electronic component; on the periphery of the first surface of the buildup wiring layer, forming second pads to be connected to an external wiring board; forming a seed layer on the surface that includes surfaces of the first and second pads; forming a first plating-resist layer having first openings to expose portions of the first pads; by applying electroplating using the seed layer as the power-supply layer, forming a solder layer on the seed layer exposed in the first openings; removing the first plating-resist layer; forming a second plating-resist layer having second openings to expose portions of the second pads; by applying electroplating using the seed layer as the power-supply layer, forming conductive posts on the seed layer exposed in the second openings; removing the second plating-resist layer; and removing unwanted exposed portions of the seed layer.

According to an embodiment of the present invention, a solder layer connected to first pads and conductive posts connected to second pads are both formed by plating. As for the power supply layer for plating, first seed layer portions on the first pads and second seed layer portions on the second pads are both formed to be part of the same seed film, thus reducing the number of manufacturing processes. Also, since conductive posts are formed by plating, they have accurate outline dimensions. Accordingly, a fine-pitch printed wiring board is obtained.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a buildup wiring layer comprising a plurality of resin insulation layers and a plurality of conductive layers such that the plurality of conductive layers is laminated on the plurality of resin insulation layers, respectively;
a plurality of first pads formed in a center portion of a first surface of the buildup wiring layer and positioned to connect an electronic component;
a plurality of second pads formed on a periphery portion of the first surface of the buildup wiring layer and positioned to connect an external wiring board;
a solder layer comprising a plating material and formed on the plurality of first pads such that the solder layer is formed on each of the first pads;
a plurality of conductive posts comprising a plating material and formed on the plurality of second pads, respectively; and
a seed layer comprising a plurality of first seed layer portions formed between the plurality of first pads and the solder layer and a plurality of second seed layer portions formed between the plurality of second pads and the plurality of conductive posts.

2. A printed wiring board according to claim 1, wherein the seed layer comprises an electroless plated copper film

3. A printed wiring board according to claim 1, wherein the plurality of conductive posts is formed such that the plurality of conductive posts has a height which is greater than a height of the solder layer.

4. A printed wiring board according to claim 1, wherein the plating material of the plurality of conductive posts comprises an electro plated copper material.

5. A printed wiring board according to claim 1, wherein the buildup layer comprises a plurality of via conductors connected to the first pads and the second pads, respectively, and formed such that each of the via conductors has a diameter which is decreasing from the first surface of the buildup layer toward a second surface of the buildup layer on an opposite side with respect to the first surface.

6. A printed wiring board according to claim 1, wherein the buildup layer comprises a plurality of via conductors connected to the first pads and the second pads, respectively, and formed such that each of the via conductors has a diameter which is increasing from the first surface of the buildup layer toward a second surface of the buildup layer on an opposite side with respect to the first surface.

7. A printed wiring board according to claim 1, further comprising:
a base plate formed on a second surface of the buildup layer on an opposite side with respect to the first surface.

8. A printed wiring board according to claim 7, wherein the base plate comprises a prepreg material.

9. A printed wiring board according to claim 7, wherein the base plate comprises a metal plate.

10. A printed wiring board according to claim 2, wherein the plurality of conductive posts is formed such that the plurality of conductive posts has a height which is greater than a height of the solder layer.

11. A printed wiring board according to claim 2, wherein the plating material of the plurality of conductive posts comprises an electro plated copper material.

12. A printed wiring board according to claim 2, wherein the buildup layer comprises a plurality of via conductors connected to the first pads and the second pads, respectively, and formed such that each of the via conductors has a diameter which is decreasing from the first surface of the buildup layer toward a second surface of the buildup layer on an opposite side with respect to the first surface.

13. A printed wiring board according to claim 2, wherein the buildup layer comprises a plurality of via conductors connected to the first pads and the second pads, respectively, and formed such that each of the via conductors has a diameter which is increasing from the first surface of the buildup layer toward a second surface of the buildup layer on an opposite side with respect to the first surface.

14. A semiconductor package, comprising:
a printed wiring board;
a first semiconductor element mounted on a surface of the printed wiring board; and
an external wiring board mounted on the surface of the printed wiring board,
wherein the printed wiring board comprises a buildup wiring layer comprising a plurality of resin insulation layers and a plurality of conductive layers such that the plurality of conductive layers is laminated on the plurality of resin insulation layers, respectively, a plurality of first pads formed in a center portion of a first surface of the buildup wiring layer and positioned to connect the first semiconductor element to the surface of the printed wiring board, a plurality of second pads formed on a periphery portion of the first surface of the buildup wiring layer and positioned to connect the external wiring board to the surface of the printed wiring board, a solder layer comprising a plating material and formed on the plurality of first pads such that the solder layer is formed on each of the first pads, a plurality of conductive posts comprising a plating material and formed on the plurality of second pads, respectively, and a seed layer comprising a plurality of first seed layer portions formed between the plurality of first pads and the solder layer and a plurality of second seed layer portions formed between the plurality of second pads and the plurality of conductive posts.

15. A semiconductor package according to claim 14, wherein the external wiring board has a plurality of bumps connecting to the plurality of conductive posts, respectively.

16. A semiconductor package according to claim 14, further comprising:
a second semiconductor element mounted on the external wiring board.

17. A method for manufacturing a printed wiring board, comprising:
forming a buildup wiring layer comprising a plurality of resin insulation layers and a plurality of conductive layers such that the plurality of conductive layers is laminated on the plurality of resin insulation layers, respectively;
forming a plurality of first pads in a center portion of a first surface of the buildup wiring layer such that the plurality of first pads is positioned to connect an electronic component;
forming a plurality of second pads on a periphery portion of the first surface of the buildup wiring layer such that the plurality of second pads is positioned to connect an external wiring board;
forming a seed layer on the first surface of the buildup wiring layer such that the seed layer is formed on a surface including surfaces of the first pads and second pads formed on the first surface of the buildup wiring layer;
forming on the seed layer a first plating-resist layer having a plurality of first openings such that the plurality of first openings exposes the plurality of first pads, respectively;
applying electroplating using the seed layer as a power-supply layer such that a solder layer is formed on the seed layer exposed in each of the first openings;
removing the first plating-resist layer from the seed layer;
forming on the seed layer a second plating-resist layer having a plurality of second openings such that the plurality of second openings exposes the plurality of second pads, respectively;
applying electroplating using the seed layer as a power-supply layer to the plurality of second pads such that a plurality of conductive posts is formed on the seed layer exposed in the plurality of second openings, respectively;
removing the second plating-resist layer from the seed layer; and
removing the seed layer exposed by the removing of the second plating-resist layer.

18. A method for manufacturing a printed wiring board according to claim 17, wherein the forming of the seed layer comprises applying electroless copper plating on the first surface of the buildup wiring layer such that the seed layer comprising electroless copper plating film is formed on the surface including the surfaces of the first pads and second pads formed on the first surface of the buildup wiring layer.

19. A method for manufacturing a printed wiring board according to claim 17, wherein the forming of the buildup layer comprises laminating on a base plate the plurality of resin insulation layers and the plurality of conductive layers, and the base plate is removed prior to the forming of the seed layer.

20. A method for manufacturing a printed wiring board according to claim 17, wherein the forming of the buildup layer comprises laminating on a base plate the plurality of resin insulation layers and the plurality of conductive layers, and the base plate is removed after the removing of the seed layer exposed by the removing of the second plating-resist layer.
